(19) United States
(12) Patent Application Publication
(10) Pub. No.: US 2013/0313663 A1
(43) Pub. Date: Nov. 28, 2013

(54) CAPACITIVE ELECTROMECHANICAL TRANSDUCER

(71) Applicants: Ayako Kato, Kawasaki-shi (JP); Kazutoshi Torashima, Yokohama-shi (JP); Yasuhiro Soeda, Yokohama-shi (JP); Shinichiro Watanabe, Kawasaki-shi (JP)

(72) Inventors: Ayako Kato, Kawasaki-shi (JP); Kazutoshi Torashima, Yokohama-shi (JP); Yasuhiro Soeda, Yokohama-shi (JP); Shinichiro Watanabe, Kawasaki-shi (JP)

(73) Assignee: CANON KABUSHIKI KAISHA, Tokyo (JP)

(21) Appl. No.: 13/983,287

(22) PCT Filed: Jan. 16, 2012
(86) PCT No.: PCT/JP2012/051281

§ 371 Date: Aug. 1, 2013

(30) Foreign Application Priority Data
Feb. 11, 2011 (JP) 2011-027965

(51) Int. Cl. H01L 29/84

(52) U.S. Cl. CPC H01L 29/84
USPC 257/416

(57) ABSTRACT

Provided is a capacitive electromechanical transducer manufactured by fusion bonding, which is capable of enhancing the performance by reducing fluctuations in initial deformation among diaphragms caused at positions having difference boundary conditions such as the bonding area. The capacitive electromechanical transducer includes a device, the device including at least one cellular structure including: a silicon substrate; a diaphragm; and a diaphragm supporting portion configured to support the diaphragm so that a gap is formed between one surface of the silicon substrate and the diaphragm. The device has, in its periphery, a groove formed in a layer shared with the diaphragm supporting portion.

### TECHNICAL FIELD

The present invention relates to a capacitive electromechanical transducer to be used as an ultrasound transducer or the like.

### BACKGROUND ART

Conventionally, micromechanical members to be manufactured using micromachining technology can be processed on the order of micrometers, and various functional microelements are materialized using such micromechanical members. A capacitive transducer using such technology (capacitive micromachined ultrasonic transducer (CMUT)) is being researched as an alternative to a piezoelectric element. With such a CMUT, ultrasound may be transmitted and received using vibrations of a diaphragm, and in particular, excellent broadband characteristics in a liquid may be obtained with ease. An example of the transducer is a capacitive electromechanical transducer that uses a monocrystalline silicon diaphragm formed on a silicon substrate by bonding or other methods (see Patent Literature 1). Patent Literature 1 discloses a capacitive electromechanical transducer manufactured by fusion bonding a monocrystalline silicon film onto a silicon substrate, exposing the monocrystalline silicon film after the bonding, and forming a cell having the fusion-bonded film.

Patent Literature 2 discloses a capacitive electromechanical transducer in which a signal blocking part for blocking transmission/reception of a signal generated when a diaphragm displaces or vibrates is provided outside of cells at the outermost periphery or the end of the capacitive electromechanical transducer. The disclosed structure of the capacitive electromechanical transducer enables uniform and stable operations of cells.

### CITATION LIST

### Patent Literature

PTL 1: U.S. Pat. No. 6,958,255 B2

PTL 2: WO 2008/136198 A1

### SUMMARY OF INVENTION

### Technical Problem

In the above-mentioned technologies, the capacitive electromechanical transducer can be manufactured by forming the monocrystalline silicon diaphragm on the silicon substrate by a bonding method involving high-temperature processing. In this manufacturing method, in a transducer device (element) constituting the capacitive electromechanical transducer, the bonding area around the cell varies for each cell during the bonding involving high-temperature processing, with the result that the amount of deformation of the diaphragm may vary for each cell (fluctuations in diaphragm deformation amount). The fluctuations are considered to be caused by the difference in thermal expansion coefficient between the diaphragm and an insulating layer, the difference in residual amount of moisture or gas generated when the high-temperature processing is performed, and the warp of the substrate due to internal stress in the diaphragm and the insulating layer. The fluctuations in diaphragm deformation amount for each cell lead to fluctuations in transmission efficiency and detection sensitivity of ultrasound. However, the above-mentioned technology of Patent Literature 2 is not aimed at reducing the fluctuations.

### Solution to Problem

In view of the above-mentioned problem, a capacitive electromechanical transducer according to the present invention includes a device, the device including at least one cellular structure including: a silicon substrate; a diaphragm; and a diaphragm supporting portion configured to support the diaphragm so that a gap is formed between one surface of the silicon substrate and the diaphragm. The device has, in its periphery, a groove formed in a layer shared with the diaphragm supporting portion.

### Advantageous Effects of Invention

According to the structure of the capacitive electromechanical transducer of the present invention, around the device constituting the transducer, the groove is formed in the layer shared with the diaphragm supporting portion which is a component of the cellular structure included in the device. This groove can reduce the fluctuations in initial deformation among the diaphragms of the cells within the device due to thermal stress generated in fusion bonding or the like which is performed for providing the diaphragm such as a monocrystalline silicon diaphragm. Therefore, the fluctuations in detection sensitivity and transmission efficiency of the transducer can be reduced.

### BRIEF DESCRIPTION OF DRAWINGS

FIG. 1 is a top view illustrating an electromechanical transducer according to an embodiment or Example 1 of the present invention.

FIG. 2A is a view illustrating the cross section taken along the line X-X of FIG. 1, and FIG. 2B is a view illustrating the cross section taken along the line Y-Y of FIG. 1.

FIGS. 3A, 3B, 3C, 3D, 3E, 3F, and 3G are views of the cross section taken along the line X-X of FIG. 1, illustrating a manufacturing method according to Example 1 and others.

FIG. 4 is a top view illustrating an electromechanical transducer according to Example 2 of the present invention.

FIG. 5 is a view illustrating the cross section taken along the line V-V of FIG. 4.

FIG. 6 is a top view illustrating an electromechanical transducer according to Example 3 of the present invention.

FIG. 7 is a view illustrating the cross section taken along the line W-W of FIG. 6.

FIGS. 8A and 8B are graphs showing the effects of eliminating fluctuations in diaphragm deformation amount obtained by the electromechanical transducer according to the present invention.

FIG. 9 is a top view of an example of a capacitive electromechanical transducer according to the present invention.

FIG. 10 is a top view of a device (element) of the electromechanical transducer according to the present invention.

### DESCRIPTION OF EMBODIMENTS

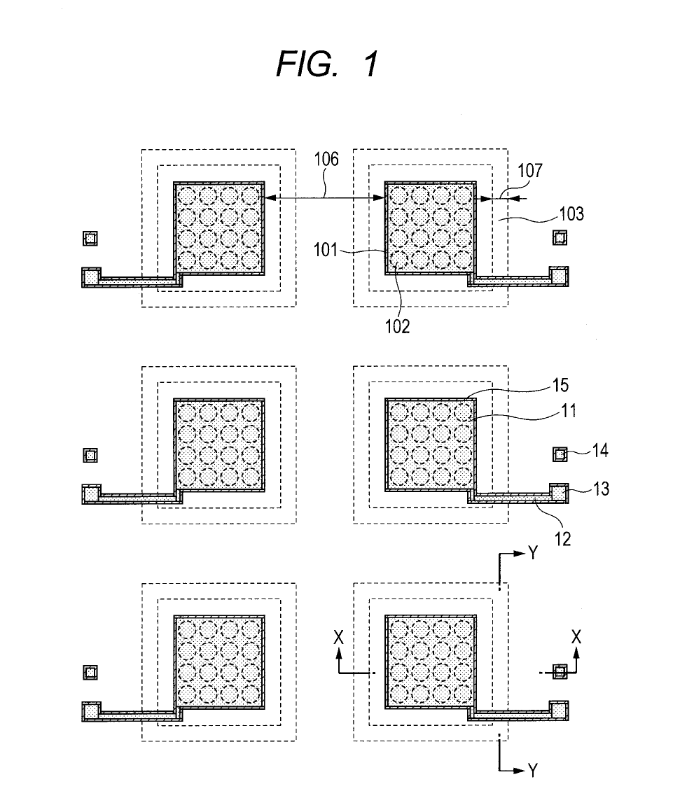

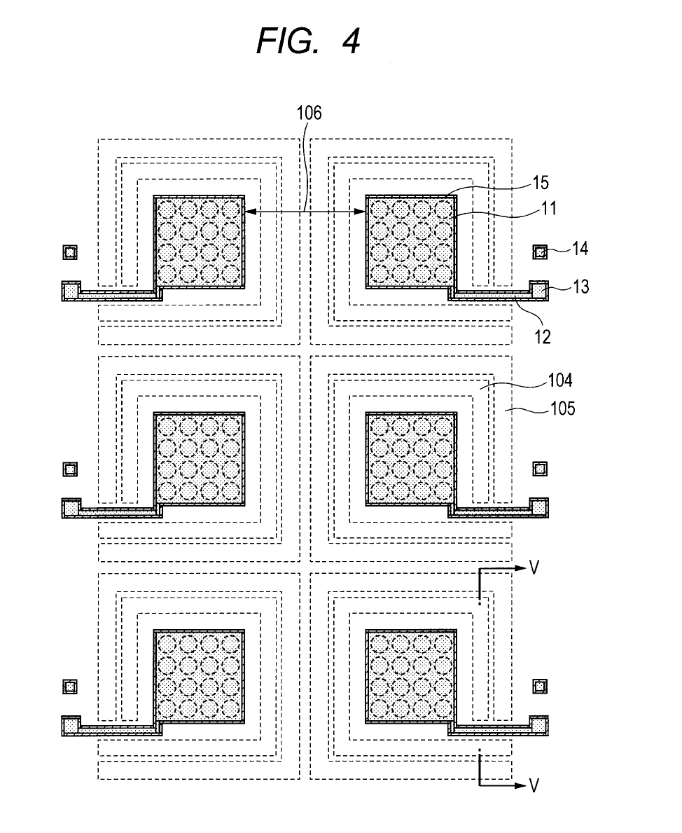

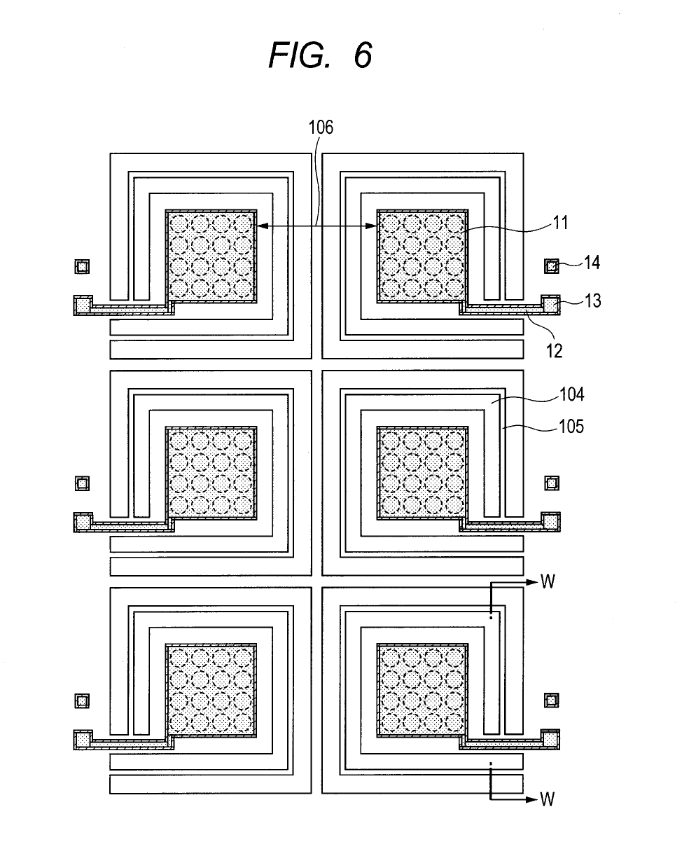

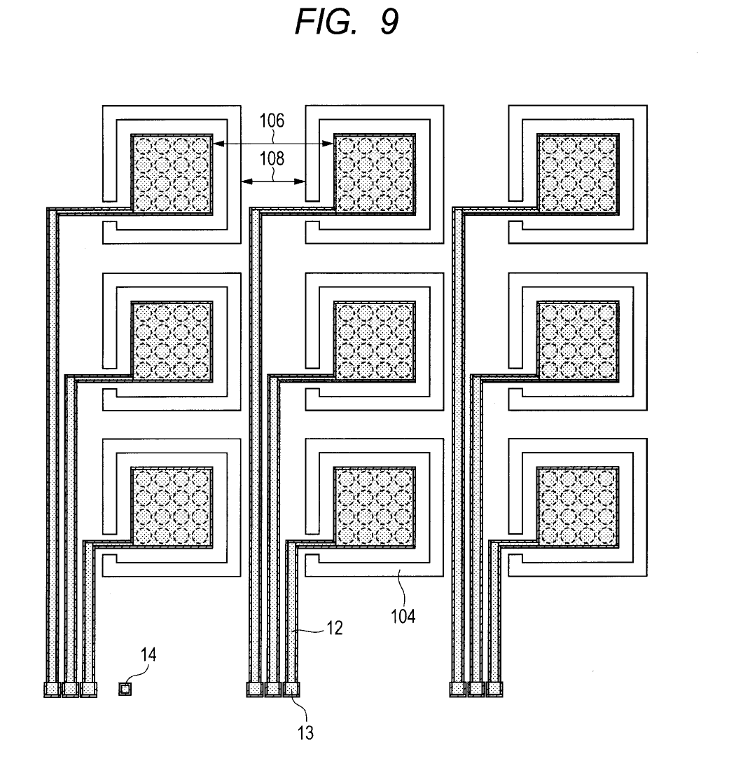

The feature of the present invention resides in that, around a device including at least one cell, a groove is formed in a layer shared with a diaphragm supporting portion for supporting a diaphragm, such as a monocrystalline silicon diaphragm. In this basic configuration, a capacitive electromechanical transducer of the present invention may employ various forms. Typically, the device and the groove are electrically insulated from each other by forming on the diaphragm a separating groove which is closed so as to surround the periphery of the device (such as in the example of FIG. 1) or by preventing the diaphragm from being present above the groove (such as in the example of FIG. 6). The groove may be a continuous closed loop groove (in the example of FIG. 1) and may be a groove having a shape with a starting point and an end point, in which the layer shared with the diaphragm supporting portion, such as an insulating layer, remains between the two points so as to separate the two points (such as in the example of FIG. 4). In the case of the loop groove, as illustrated in FIG. 1 and other figures, electrical wiring connected to an electrode of the device is formed so as to cross the loop groove. In the case of the groove having the starting point and the end point, as illustrated in FIG. 4 and other figures, electrical wiring connected to the electrode of the device is formed above the shared layer, such as an insulating layer, between the starting point and the end point of the groove. The groove or the loop groove may be formed around the device so as to enclose the device only once as illustrated in FIGS. 1 and 9, or may be formed around the device so as to enclose the device multiple times in parallel (“in parallel” means being arranged towards the same direction and refers to a literally parallel state and also a non-parallel state) as illustrated in FIG. 4 and other drawings. In any case, the groove can be formed around the device in any manner as long as the boundary conditions, such as the bonding area of each cellular structure, can be made substantially uniform to thereby reduce fluctuations in initial deformation among the diaphragms of cells within the device due to thermal stress generated in fusion bonding or the like.

Hereinafter, an embodiment of the capacitive electromechanical transducer according to the present invention is described. In the embodiment of the present invention, as illustrated in FIG. 1, multiple devices 101 each including multiple cellular structures 102 are arranged in an array. FIG. 1 illustrates only six devices, but the number of the devices is not limited thereto. The device 101 is formed of sixteen cellular structures 102, but the number of the cellular structures is not limited thereto. The planar shape of cells is circular in this embodiment, but may be quadrangular, hexagonal, or other shapes.

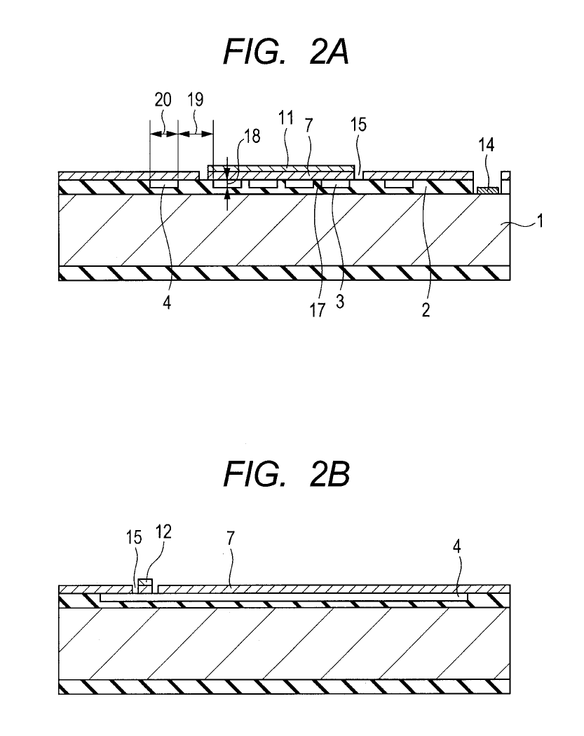

Referring to FIG. 2A illustrating the cross section of the line X-X of FIG. 1 and FIG. 2B illustrating the cross section of the line Y-Y of FIG. 1, the cellular structure 102 includes a monocrystalline silicon diaphragm 7 as a diaphragm, a gap (recess) 3 as a void, a diaphragm supporting portion 17 for supporting the diaphragm 7, and a silicon substrate 1. It is desired to use an insulator as the diaphragm supporting portion 17, such as silicon oxide and silicon nitride. Otherwise, it is necessary to form an insulating layer on the silicon substrate 1 in order to insulate the silicon substrate 1 and the monocrystalline silicon diaphragm 7 from each other. The silicon substrate 1 and the monocrystalline silicon diaphragm 7 can each be used as a common electrode or a signal extraction electrode. In order to improve the conductive characteristics of the silicon substrate 1 and the monocrystalline silicon diaphragm 7, a thin metal film such as aluminum may be formed on the silicon substrate 1 and the monocrystalline silicon diaphragm 7. It is desired that the silicon substrate 1 and the monocrystalline silicon diaphragm 7 have low resistance for promoting ohmic behavior. It is desired that the resistivity be 0.1 Ωcm or lower. The “ohmic” means that the resistance value is constant irrespective of the direction of current and the magnitude of voltage.

The device 101 has, in its periphery, a groove 103 (represented by 4 in FIGS. 2A and 2B; a closed loop groove in this embodiment) which is formed in the same layer as a layer of an diaphragm supporting portion. In this case, the groove 103 is formed around the device 101 in an insulating layer 2 shared with the diaphragm supporting portion 17. As illustrated in FIG. 1, the groove 103 is disposed as a single loop groove which is closed so as to surround the periphery of the device 101 completely. The loop groove 103 only needs to be formed in the same layer as a layer of at least the diaphragm supporting portion. With the loop groove 103 formed in the same layer 2 as the layer of the diaphragm supporting portion 17, the boundary conditions, such as the bonding area of each cellular structure, can be made substantially uniform to thereby reduce fluctuations in amount of deformation among the diaphragms 7 due to thermal stress generated in fusion bonding or the like. If there is no loop groove formed, the amount of deformation of the diaphragm in a cell disposed at the outermost periphery becomes larger than the amount of deformation of the diaphragm in a cell disposed at the center in the device, and the amount of deformation of the diaphragm in the cell becomes smaller in order from the outermost periphery to the center. This is because the bonding area around the cell at the outermost periphery is larger than the bonding area around the cell at the center, and the amount of deformation of the diaphragm in the cell at the outermost periphery becomes larger, of which influence being stronger on the diaphragm in a cell on the outer side.

In the device 101 and its periphery, the monocrystalline silicon diaphragm 7 serving as the signal extraction electrode for each device and a monocrystalline silicon film formed above the loop groove 103 are electrically separated from each other, to thereby electrically separate the device and the loop groove from each other. In the driving of the device 101, if a monocrystalline silicon film is present above the loop groove 103, the monocrystalline silicon film above the loop groove may be driven simultaneously and noise is generated. Thus, the electrical insulation between the device and the groove can reduce the noise and prevent the lowering of detection sensitivity and transmission efficiency. The electrical insulation is realized by removing the monocrystalline silicon film itself above the loop groove or by forming a separating groove 15 between the device and an inner edge portion of the loop groove. The separating groove 15 as the latter method is provided in this case, but the former method is employed in an example of FIG. 6 to be described later. The inner edge portion of the loop groove means one end surface of a region 20 in which the loop groove is provided, the one end surface being closer to the recess of the gap 3. In FIG. 1, the separating groove 15 serves as the electrical separation between the recess and the loop groove and the formation of the signal extraction electrode.

The monocrystalline silicon diaphragm 7 may be used as a common electrode, and the silicon substrate 1 may be divided so that the divided silicon substrates are each used as a signal extraction electrode for extracting a signal for each device. Also in this configuration, the electrical insulation between the loop groove and the device can be performed. In this embodiment, the device refers to a region inside the separating groove 15, specifically, a portion excluding wiring 12, a first electrode pad 13, and a second electrode pad 14 to be described later. The above-mentioned configuration can enhance the uniformity of the device and the device array, thereby stabilizing receiving sensitivity and the like.

The drive principle of this embodiment is as follows. In the case of receiving ultrasound by a capacitive electromechanical transducer, a direct voltage is kept applied to the monocrystalline silicon diaphragm 7 by a voltage applying unit (not shown). When ultrasound is received, the diaphragm 7 is deformed, and a distance 18, specifically the distance between the monocrystalline silicon diaphragm 7 (signal extraction electrode) and the silicon substrate 1 (common electrode), varies to change the capacitance. This change in capacitance causes a current to flow through the diaphragm 7. This current is converted into a voltage by a current-to-voltage converter (not shown), which is then output as a reception signal of ultrasound. Conversely, when a direct voltage and an alternating voltage are applied to the monocrystalline silicon diaphragm 7, the diaphragm 7 may be vibrated by electrostatic force. In this way, ultrasound can be transmitted.

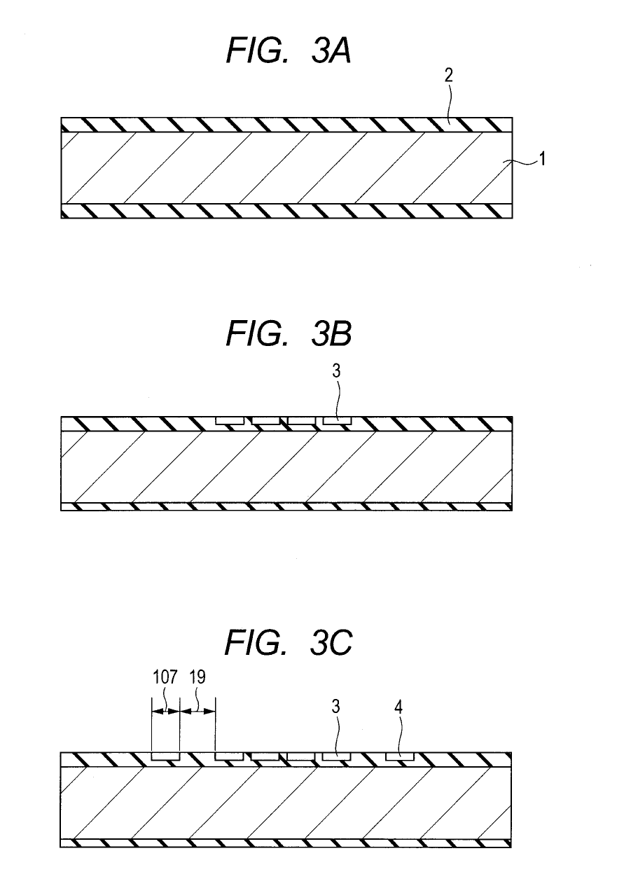

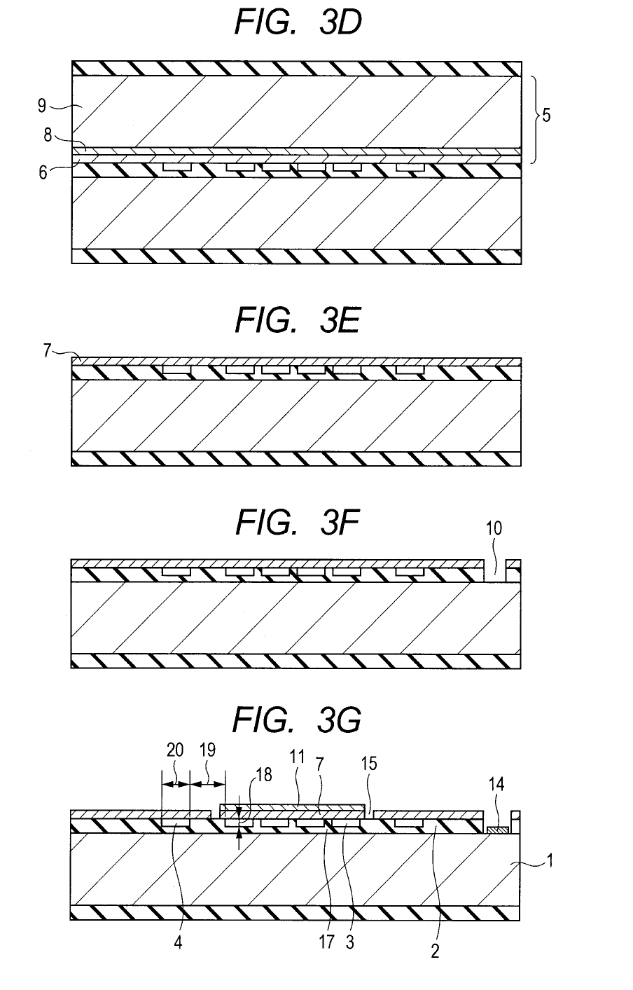

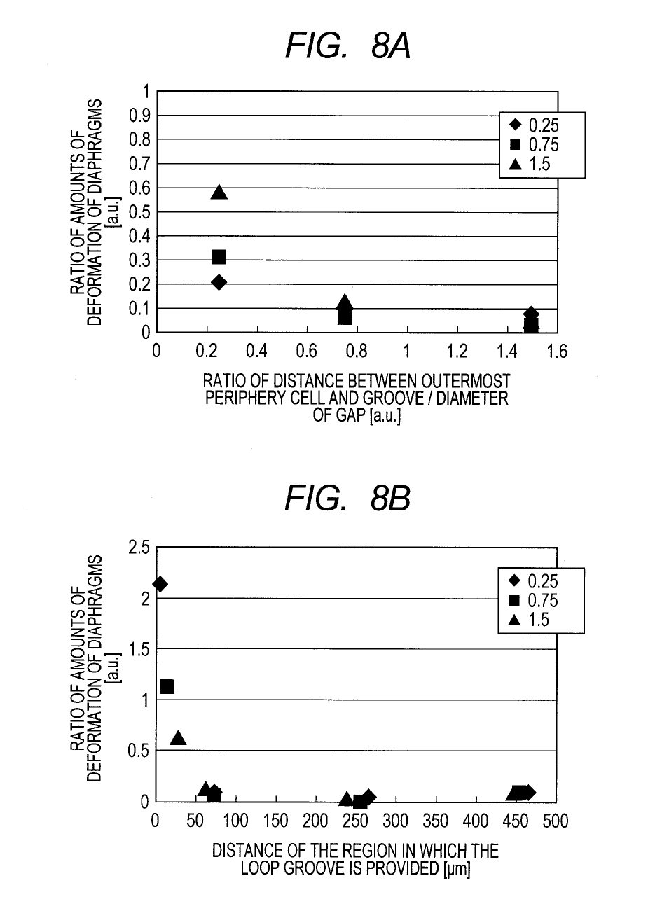

Referring to FIGS. 8A and 8B, the effects of this embodiment are described. FIG. 8A shows the relation between the fluctuations in diaphragm deformation amount and the distance between the cell at the outermost periphery and the groove. FIG. 8B shows the relation between the fluctuations in diaphragm deformation amount and the region in which the groove is provided. The horizontal axis of FIG. 8A represents the ratio of a distance 19 between the cell at the outermost periphery and the groove with respect to the diameter of the gap 3. The vertical axis of FIG. 8A represents an absolute value of the difference between the amount of deformation of the diaphragm in the cell at the outermost periphery and the amount of the deformation of the diaphragm in the cell at the center portion in the case where the groove is provided, in the form of the ratio with respect to an absolute value of the amount of deformation of the diaphragm in the cell at the center portion. A larger ratio of the vertical axis indicates larger fluctuations in transmitting or receiving sensitivity. In other words, if an electromechanical transducer has near 0 amount of the above-mentioned absolute value of the difference in diaphragm deformations, the performance uniformity within the device or among the devices is higher, and the receiving sensitivity and the like can be stabilized. FIG. 8A shows the case where the region 20 in which the groove is provided is 100 μm. The series in the graph indicate the difference in groove width 107 (see FIGS. 1 and 3C), and the figures such as 0.25 indicates the ratio of the groove width 107 with respect to the diameter of the gap 3. For example, in the case where the diameter of the gap 3 is 35 μm, the groove width for the series 0.25 is 8.75 μm, the groove width for the series 0.75 is 26.25 μm, and the groove width for the series 1.5 is 52.5 μm. Depending on the difference in groove width, the number of loops of the groove (the number of grooves) to be provided in the region 20 varies. As shown in FIG. 8A, even when the number of grooves is different, the fluctuations in diaphragm deformation amount are reduced by increasing the distance between the cell at the outermost periphery and the groove.

Referring to FIG. 8A, when the ratio of the distance 19 between the cell at the outermost periphery and the groove with respect to the diameter of the gap 3 is 0.5 or more, the above-mentioned difference in diaphragm deformation amount is substantially 0. It is therefore preferred that the ratio of the distance 19 between the cell at the outermost periphery and the groove with respect to the diameter of the gap 3 be 0.5 or more. The monocrystalline silicon film formed above the groove is more likely to be deformed than the diaphragm of the cell, and hence, if the groove is too close to the gap 3, the deformation of the monocrystalline silicon film formed above the groove affects the diaphragm 7 of the cell to increase the amount of deformation of the diaphragm 7. On the other hand, when the above-mentioned ratio increases, that is, the state is closer to the state in which no groove is provided, the boundary conditions such as the bonding area become non-uniform, and the above-mentioned difference in diaphragm deformation amount increases. It is therefore preferred that the ratio of the distance 19 between the cell at the outermost periphery and the groove with respect to the diameter of the gap 3 be in the range of from about 0.5 to about 2.0.

The horizontal axis of FIG. 8B represents the distance of the region 20 in which the loop groove is provided, and the vertical axis thereof represents the same as in FIG. 8A. The series of the graph are also the same as in FIG. 8A. FIG. 8B shows the case where the ratio of the distance 19 between the outermost gap end surface and the groove end surface with respect to the diameter of the gap 3 is 0.75. Referring to FIG. 8B, when the region 20 in which the groove is provided is 50 μm or more, the above-mentioned difference in diaphragm deformation amount is substantially 0. It is therefore preferred that the region 20 in which the loop groove is provided be 50 μm or more because it is possible to significantly reduce the fluctuations in receiving sensitivity and transmission efficiency. Although the number of loops of the groove (the number of grooves) varies depending on the difference in series such as 0.25, the groove only needs to be provided in the region 20 so as to enclose the device at least once. FIG. 8B shows the case where the ratio is 0.75, but, even when the ratio is other than 0.75, the fluctuations in diaphragm deformation amount are similarly reduced by increasing the distance of the region 20 in which the groove is provided.

The fluctuations in diaphragm deformation amount can be reduced also by providing a structure equivalent to the cellular structure around the device. This method, however, needs a larger region than providing a groove typified by the above-mentioned loop groove, in order to sufficiently reduce the fluctuations in amount of deformation. Therefore, in the case of a capacitive electromechanical transducer in which the devices are arranged in an array as illustrated in FIG. 9 to be described later, the structure equivalent to the cellular structure formed around the device may hinder the extraction of lead-out wiring. On the other hand, in the case of the loop groove as in this embodiment, the amounts of deformation of the diaphragms can be made uniform by disposing the loop groove in a narrower region than the structure equivalent to the cellular structure. Therefore, even when an arrangement interval 106 of the devices is small, the wiring can be led out.

Referring back to FIGS. 1, 2A, and 2B, the depth of the groove 103 illustrated in those figures (the groove 4 of FIGS. 2A and 2B) may be set to a desired depth, but it is preferred to set the groove to such a depth that the insulating layer 2 remains at the bottom portion of the groove 103. With the insulating layer 2 remaining at the bottom portion of the groove 103, the exposure of the silicon substrate 1 can be prevented when the monocrystalline silicon film above the groove is removed (see Example 3 to be described later). By preventing the exposure of the silicon substrate 1, it is possible to prevent short-circuit between an electrode 11 and the silicon substrate 1, which is otherwise caused when an external conductive substance is adhered between the electrode 11 on the diaphragm 7 and the groove 103. By setting the groove 103 and the gap 3 to have the same depth, it is also possible to form the gap 3 and the groove 103 at the same time. This realizes the reduction in number of photomasks, the reduction in number of manufacturing processes, the prevention of misalignment, and the like.

The width 107 of the groove 103 can be set to a desired value. As shown in FIG. 8A, even when the distance 19 between the cell at the outermost periphery and the groove is small, the difference in diaphragm deformation amount can be reduced by providing a narrower groove width 107. In this case, the groove can be formed in the vicinity of the cell at the outermost periphery, and hence a wiring region 108 (see FIG. 9) can be widened so as to extract a larger number of wirings. It is preferred that the width 107 be set so that a monocrystalline silicon film formed above the groove 103 does not contact the bottom portion of the groove. When the groove width is set smaller than the diameter of the gap 3, the monocrystalline silicon film formed above the groove does not contact the bottom portion. It is therefore preferred that the width of the groove be equal to or smaller than the diameter of the gap 3.

In the case where the width 107 of the groove is larger than the diameter of the gap (recess) 3, and the amount of deformation of the monocrystalline silicon film above the groove is larger than the amount of deformation of the monocrystalline silicon diaphragm formed above the recess 3, the following problem occurs. If a voltage is applied to the electromechanical transducer in the state in which an external conductive substance or the like is still adhered between the electrode 11 and the groove 103, the monocrystalline silicon film formed above the groove contacts the silicon substrate 1 before the monocrystalline silicon diaphragm formed above the recess 3 does. When the application voltage is further increased, breakdown occurs between the monocrystalline silicon film formed above the groove and the silicon substrate 1, resulting in a fear that the electromechanical transducer does not work any more. From this viewpoint, it is preferred that the groove width 107 be substantially equal to or smaller than the diameter of the gap 3.

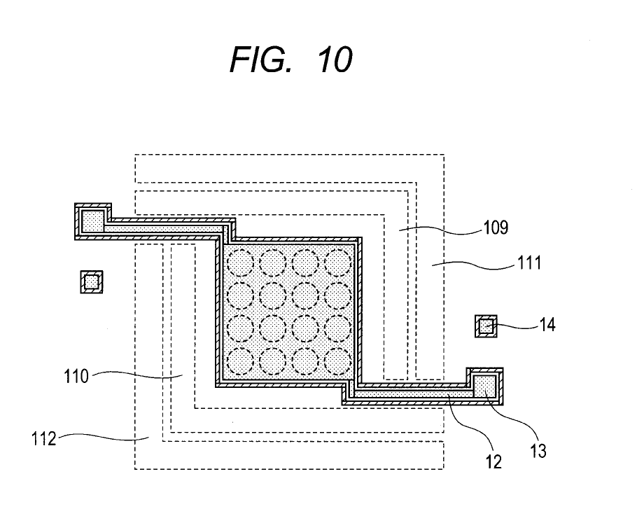

The groove may be structured so that its starting point and end point are located at different positions. The structure in which the starting point and the end point are located at different positions means a structure in which the groove provided around the device is disconnected in part as illustrated in FIGS. 9 and 10. In this structure, as illustrated in FIG. 9, the wiring 12 and the like can be formed between a starting point and an end point of a groove 104. The width between the starting point and the end point of the groove only needs to be wide enough to form the wiring and the like therebetween. The disconnection between the starting point and the end point of the groove may be in various forms, and the groove may have any shape such as the U-shape, the L-shape, and the C-shape. Alternatively, it is also possible to adopt a structure in which grooves are arranged side by side in the form of a spiral without connecting the starting points and the end points to each other, and the form is not particularly limited.

Electrical wiring may be formed between the starting point and the end point of the groove. In the configurations of FIGS. 9 and 10, no gap (groove) is provided under the electrical wiring 12, and hence the occurrence of noise in the electrical wiring is prevented and, as compared to the case where the gap is provided under the wiring, the strength of the wiring can also be maintained. It is also possible to form the grooves around the device so as to enclose the device multiple times. This configuration can further reduce the fluctuations in diaphragm deformation amount. As an example of this type, as illustrated in FIG. 10, multiple L-shaped grooves 109, 110, 111, and 112, in each of which the starting point and the end point are located at different positions, may be used so as to enclose the device multiple times. This configuration provides multiple locations where the starting point and the end point are separated from each other, to thereby enable the lead-out of the electrical wiring from multiple locations. It is also possible to remove the silicon film above the groove. This prevents the occurrence of noise in the monocrystalline silicon diaphragm 7 formed above the gap 3, which is otherwise caused when the silicon film above the groove vibrates. Note that, in the configuration of FIG. 9, the diaphragm is removed in portions excluding the device and the wiring, and in the configuration of FIG. 10, the silicon film is present above the grooves 109, 110, 111, and 112.

In the following, the present invention is described in detail by way of more specific examples.

### EXAMPLE 1

A configuration of a capacitive electromechanical transducer according to Example 1 is described with reference to FIGS. 1, 2A, and 2B. A manufacturing method therefor is also described with reference to FIGS. 3A to 3G. As illustrated in FIG. 1 illustrating the top surface structure of Example 1, six devices 101 are arranged in an array in Example 1. The dimensions of the device 101 are 1 mm×1 mm. Cellular structures 102 constituting the device 101 are arranged in 20 rows and 20 columns (FIGS. 1 and 2A omit some cellular structures).

A loop groove 103 is provided so as to surround the device 101 described above. The width of the loop groove is 45 μm, which is equal to the diameter of a gap 3 of the cellular structure. With the width of the loop groove 103 equal to the diameter of the gap 3 of the cellular structure, a monocrystalline silicon film formed above the loop groove can be prevented from contacting the bottom portion of the loop groove. Wiring 12 is led out to a first electrode pad 13 from an upper electrode 11 while passing above the loop groove 103, with a length of 1 mm and a width of 15 μm. The dimensions of the first electrode pad 13 and a second electrode pad 14 are 200 μm, which are disposed at an interval of 500 μm. A separating groove 15 is provided at the position electrically separating the device 101 and the loop groove 103 from each other. In FIG. 1, the separating groove 15 is provided so as to surround the device 101, the wiring 12, and the first electrode pad 13. The width of the separating groove 15 is 10 μm. The region inside the separating groove 15 excluding the wiring 12 and the first electrode pad 13 corresponds to the dimensions of the device 101. An arrangement interval 106 of the devices 101 is 1 mm. The dimensions of an electrode 11 are 1 mm×1 mm.

Referring to FIGS. 2A and 2B, the cross-sectional structure of Example 1 is described. As illustrated in FIGS. 2A and 2B, the cellular structure constituting the device is formed by the monocrystalline silicon diaphragm 7 having a thickness of 1.25 μm, the gap 3 having a diameter of 45 μm, the insulating layer 2 having a thickness of 0.2 μm, and the first silicon substrate 1 having a thickness of 0.5 mm. The arrangement interval of the cellular structures is 50 μm. The resistivity of the first silicon substrate 1 is 0.01 Ωcm. The distance between the monocrystalline silicon diaphragm 7 and the first silicon substrate 1 is 0.2 μm. The thickness of the electrode 11 is 0.2 μm. The thickness of each of the first electrode pad 13, the second electrode pad 14, and the wiring 12 is 0.2 μm. The depth of a loop groove 4 (the same as the loop groove 103 of FIG. 1) is 0.2 μm, which is the same as a depth 18 of the gap 3. A distance 19 between an end surface of the cell at the outermost periphery and an end surface of the loop groove is 45 μm, which is the same as the diameter of the gap 3. With the distance 19 equal to the diameter of the gap 3, the fluctuations in amount of deformation of the diaphragm 7 can be reduced. A region 20 for providing the loop groove 4 is 45 μm. In Example 1, the inside of the gap 3 is in an almost vacuum state.

In the device 101 of Example 1, the difference in amount of deformation under atmospheric pressure between the diaphragm of the cell at the outermost periphery and the diaphragm of the cell at the center portion is about 5 nm. On the other hand, the device of a capacitive electromechanical transducer which has no loop groove has the above-mentioned difference in amount of deformation of about 40 nm under atmospheric pressure. As described above, the structure having the groove can reduce the fluctuations in diaphragm deformation amount and reduce the fluctuations in detection sensitivity and transmission efficiency significantly.

In Example 1, the loop groove is provided so as to surround the device completely, and the wiring 12 is formed above the loop groove. Alternatively, however, the wiring 12 and the separating groove 15 may be eliminated and the first silicon substrate 1 may be divided between the loop groove 4 and the device 101 so that a signal is extracted from the rear side.

The capacitive electromechanical transducer of Example 1 can be manufactured by the following method, for example. First, as illustrated in FIG. 3A, the insulating layer (insulating film) 2 is formed on the first silicon substrate 1. The resistivity of the first silicon substrate 1 is 0.01 Ωcm. The insulating layer 2 is silicon oxide formed by thermal oxidation, the thickness of which is 400 nm. Silicon oxide formed by thermal oxidation has a very small surface roughness, and, even if silicon oxide is formed on the first silicon substrate, the roughness is prevented from increasing from the surface roughness of the first silicon substrate. The surface roughness Rms is 0.2 nm or less. When fusion bonding is performed, if the surface roughness is large, for example, Rms=0.5 nm or more, the bonding is difficult to achieve, thus causing a bonding failure. The silicon oxide formed by thermal oxidation does not increase the surface roughness and it is less likely to cause a bonding failure. Thus, the manufacturing yields can be improved.

Next, as illustrated in FIG. 3B, the gap (recess) 3 is formed. The gap 3 can be formed by wet etching. The depth of the gap 3 (distance 18) is 200 nm, and the diameter thereof is 45 μm. An arrangement interval of the gaps 3 is 50 μm. Although omitted in FIG. 3B, the gaps 3 are formed in 20 rows and 20 columns. The gap 3 corresponds to the dielectric of a capacitor.

Next, as illustrated in FIG. 3C, the loop groove 4 is formed. The loop groove 4 can be formed by wet etching. The depth of the loop groove is 200 nm. The horizontal width 107 of the loop groove is 45 μm, which is the same as the diameter of the gap 3. As illustrated in FIG. 3C, the loop groove is formed so as to surround the periphery of the gap 3 completely. The distance 19 between the cell at the outermost periphery and the loop groove is 45 μm.

Next, as illustrated in FIG. 3D, the second silicon substrate 5 is fusion bonded. The fusion bonding is performed under vacuum conditions, in which the inside of the recess 3 is in an almost vacuum state. As the second silicon substrate, a silicon-on-insulator (SOI) substrate is used, and an active layer 6 in the SOI substrate is bonded. The active layer 6 is used as the monocrystalline silicon diaphragm 7. The thickness of the active layer 6 is 1.25 μm, and the thickness fluctuations are within ±5%. The resistivity of the active layer 6 is 0.01 Ωcm. Annealing temperature after the bonding is 1,000° C., and annealing time is 4 hours.

Next, as illustrated in FIG. 3E, the second silicon substrate 5 is thinned, and the monocrystalline silicon diaphragm 7 is formed. As illustrated in FIG. 3E, the thinning of the SOI substrate used as the second silicon substrate is performed by removing a handle layer 8 and a buried oxide (BOX) layer 9. The handle layer 8 is removed by grinding. The BOX layer 9 is removed by wet etching using hydrofluoric acid. The use of wet etching using hydrofluoric acid prevents silicon from being etched, and hence the fluctuations in thickness of the monocrystalline silicon diaphragm 7 caused by etching can be reduced.

Next, as illustrated in FIG. 3F, a contact hole 10 is formed in order to establish conduction of the first silicon substrate 1 from the side on which the diaphragm 7 is formed. First, a part of the diaphragm 7 in a region in which the contact hole is to be formed is removed by dry etching. Next, the insulating layer 2 is removed by wet etching. Then, the first silicon substrate 1 is exposed, and the contact hole 10 can be formed.

Next, as illustrated in FIGS. 3G and 1, the upper electrode 11, the wiring 12, and the electrode pad, which are necessary for applying a voltage to the device 101, are provided. First, an aluminum (Al) film is formed to a thickness of 200 nm, and the electrode 11, the wiring 12, the first electrode pad 13, and the second electrode pad 14 are formed by patterning. Next, the separating groove 15 is formed in the monocrystalline silicon diaphragm 7. The separating groove can be formed by dry etching. The separating groove 15 electrically insulates the gap 3 and the loop groove 4 from each other. Through the application of a voltage between the first electrode pad 13 and the second electrode pad 14, a voltage can be applied to the device 101. In this way, the capacitive electromechanical transducer of Example 1 can be manufactured.

### EXAMPLE 2

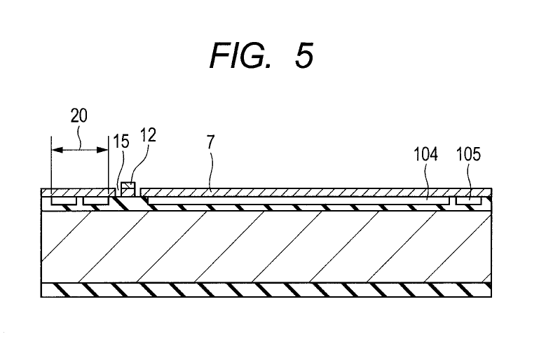

A configuration of a capacitive electromechanical transducer according to Example 2 is described with reference to FIGS. 4 and 5. FIG. 5 is a cross-sectional view taken along the line V-V of FIG. 4. As illustrated in FIG. 4, the structure except for the loop groove is the same as that of Example 1. In FIG. 4, as the groove, a second groove 104 and a third groove 105 are formed. With two (double) or more grooves provided, the fluctuations in diaphragm deformation amount can be reduced more as compared to the case of providing one (single) groove. Each of the grooves provided in FIG. 4 is an almost-enclosing groove but it is not closed, in which the starting point and the end point are located at different positions. The interval between the starting point and the end point of the second groove 104 which is internally located is 45 μm. Because the starting point and the end point of each groove are located at different positions, the wiring 12 can be formed between the starting point and the end point of each groove. The width of each of the second groove 104 and the third groove 105 is 45 μm, which is the same as the diameter of the cellular structure.

The wiring 12 is led out to the first electrode pad 13 from the upper electrode 11 while passing between the starting points and the end points of the second groove 104 and the third groove 105, with a length of 1 mm and a width of 15 μm. The dimensions of the first electrode pad 13 and the second electrode pad 14 are 200 μm, both of which are disposed at an interval of 500 μm.

Referring to FIG. 5, the cross-sectional structure of Example 2 is described. As illustrated in FIG. 5, the structure except for the region 20 in which the grooves are provided and the wiring 12 is the same as that of Example 1. In FIG. 5, the second groove 104 and the third groove 105 are provided, and the region 20 in which the grooves are provided is 90 μm. The wiring 12 is formed on a monocrystalline silicon film sandwiched between the separating grooves 15 on the insulating layer 2. The inside of the gap 3 is in an almost vacuum state.

In the device of Example 2, the difference in amount of deformation under atmospheric pressure between the diaphragm of the cell at the outermost periphery and the diaphragm of the cell at the center portion is about 1 nm. On the other hand, the device of a capacitive electromechanical transducer which omits the process of FIG. 3C, that is, which has no groove has the above-mentioned difference in amount of deformation of about 40 nm under atmospheric pressure. As described above, with two or more grooves provided, the fluctuations in diaphragm deformation amount can be reduced more and the fluctuations in detection sensitivity and transmission efficiency can be reduced significantly as compared to the case of providing one groove. Further, with the structure having the groove in which the starting point and the end point are located at different positions, the wiring can be formed between the starting point and the end point so as to transmit and receive an electrical signal. No gap is provided under the electrical wiring, and hence the electrical wiring can be prevented from vibrating during reception or transmission. Therefore, the occurrence of noise in the electrical wiring can be prevented. Besides, as compared to the case where the gap is provided under the wiring, the strength of the wiring can also be maintained.

The capacitive electromechanical transducer of Example 2 can be manufactured by the same manufacturing method as in Example 1. It is also possible to form the gap and the groove of FIGS. 3B and 3C of Example 1 by using the same photomask. Therefore, the number of manufacturing processes can be reduced, and, since no alignment is needed, no alignment error occurs between the formation of the gap and the formation of the groove. In addition, as illustrated in FIG. 10, it is also possible to form a groove structure in which multiple grooves, in each of which the starting point and the end point are located at different positions, such as the L-shaped grooves, are used to constitute a double enclosure. The groove structure constituting the double enclosure provides multiple locations where the starting point and the end point are separated from each other, to thereby enable the lead-out of the electrical wiring from multiple locations.

### EXAMPLE 3

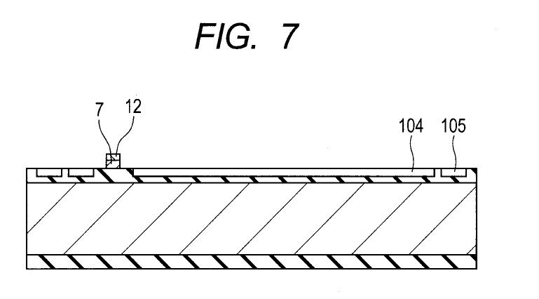

A configuration of a capacitive electromechanical transducer according to Example 3 is described with reference to FIGS. 6 and 7. FIG. 7 is a cross-sectional view taken along the line W-W of FIG. 6. In Example 3, grooves equivalent to the grooves of Example 2 are provided, and a monocrystalline silicon film above the grooves is removed, to thereby electrically insulate the device and the groove from each other.

As illustrated in FIGS. 6 and 7, Example 3 is substantially the same as Example 2. The feature of Example 3 different from that of Example 2 resides in that no monocrystalline silicon film is provided above the almost-enclosing double grooves. By removing the monocrystalline silicon film above the grooves, it is possible to prevent the monocrystalline silicon film above the grooves from vibrating at the time of reception or transmission, to thereby prevent the occurrence of noise in the monocrystalline silicon diaphragm of the device.

The capacitive electromechanical transducer of Example 3 can be manufactured through the same processes of FIGS. 3A to 3F in the manufacturing method of Example 1. To manufacture the capacitive electromechanical transducer of Example 3, the following additional processes are performed. First, an Al film is formed to a thickness of 200 nm, and the electrode 11, the wiring 12, the first electrode pad 13, and the second electrode pad 14 are formed by patterning. Next, silicon is removed by dry etching. This process removes a monocrystalline silicon film excluding a monocrystalline silicon diaphragm provided on the device, thereby electrically insulating the device and the groove from each other.

Also in Example 3, an insulating film is provided on the bottom surface of the grooves 104 and 105. The insulating film prevents the exposure of the first silicon substrate 1, thereby preventing short-circuit between the electrode 11 and the first silicon substrate 1, which is otherwise caused when an external conductive substance is adhered between the upper electrode 11 and the groove 104 or 105. In the device of Example 3, the difference in amount of deformation under atmospheric pressure between the diaphragm of the cell at the outermost periphery and the diaphragm of the cell at the center portion is about 1 nm. On the other hand, the device of the capacitive electromechanical transducer having no groove has the above-mentioned difference in amount of deformation of about 40 nm under atmospheric pressure. As described above, Example 3 can also provide the same effects as in Example 2.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-027965, filed Feb. 11, 2011, which is hereby incorporated by reference herein in its entirety.

1. A capacitive electromechanical transducer, comprising a device,
the device comprising at least one cellular structure comprising:
a silicon substrate;
a diaphragm; and
a diaphragm supporting portion configured to support the diaphragm so that a gap is formed between one surface of the silicon substrate and the diaphragm,
wherein the device has, in its periphery, a groove formed in a layer shared with the diaphragm supporting portion.

2. The capacitive electromechanical transducer according to claim 1, wherein the diaphragm comprises a monocrystalline silicon diaphragm.

3. The capacitive electromechanical transducer according to claim 1, wherein the device and the groove are electrically insulated from each other by one of forming on the diaphragm a separating groove, which is closed so as to surround the periphery of the device, and preventing the diaphragm from being present above the groove.

4. The capacitive electromechanical transducer according to claim 1, wherein the groove comprises a continuous closed loop groove.

5. The capacitive electromechanical transducer according to claim 4, further comprising electrical wiring connected to an electrode of the device, the electrical wiring being formed so as to cross the continuous closed loop groove.

6. The capacitive electromechanical transducer according to claim 1, wherein the groove has a starting point and an end point, in which the layer shared with the diaphragm supporting portion is positioned between the starting point and the end point.

7. The capacitive electromechanical transducer according to claim 6, further comprising electrical wiring connected to an electrode of the device, the electrical wiring being formed above the layer shared with the diaphragm supporting portion and between the starting point and the end point of the groove.

8. The capacitive electromechanical transducer according to claim 1, wherein one of the groove and the continuous closed loop groove is formed in parallel around the device so as to enclose the device multiple times.

9. The capacitive electromechanical transducer according to claim 1, wherein the layer shared with the diaphragm supporting portion comprises an insulating layer.
